(19) United States
(12) Patent Application Publication
(10) Pub. No.: US 2025/0048852 A1
(43) Pub. Date: Feb. 6, 2025

(54) DISPLAY DEVICE AND METHOD OF MANUFACTURING THE SAME

(71) Applicant: Samsung Display Co., LTD., Yongin-si (KR)

(72) Inventor: XINXING LI, Yongin-si (KR)

(21) Appl. No.: 18/636,893

(22) Filed: Apr. 16, 2024

(30) Foreign Application Priority Data
Aug. 2, 2023 (KR) 10-2023-0100875

(51) Int. Cl. H10K 59/123; H10K 59/12; H10K 59/121; H10K 59/122; H10K 71/60

(52) U.S. Cl. CPC H10K 59/123; H10K 59/1201; H10K 59/1213; H10K 59/122; H10K 71/60

(57) ABSTRACT

A display device includes a substrate including a main pixel area, and an auxiliary pixel area adjacent to the main pixel area, a main transistor above the substrate, and overlapping the main pixel area, an auxiliary transistor above the substrate, and overlapping the auxiliary pixel area, a lower electrode above the main transistor, connected to the main transistor, and overlapping the main pixel area, a pixel-defining layer above the substrate, covering a side portion of the lower electrode, overlapping the auxiliary pixel area, and defining a cutout portion, and an auxiliary lower electrode filling the cutout portion, connected to the auxiliary transistor, and having a same height as the cutout portion.

### CROSS-REFERENCE TO RELATED APPLICATION

The present application claims priority to, and the benefit of, Korean Patent Application No. 10-2023-0100875, filed on Aug. 2, 2023, in the Korean Intellectual Property Office (KIPO), the entire disclosure of which is incorporated herein by reference.

### BACKGROUND

### 1. Field

Embodiments relate to a display device and a method of manufacturing the same.

### 2. Description of the Related Art

An organic light-emitting display device may include pixels. Each of the pixels may include a light-emitting element. The light-emitting element may include an anode, a cathode, and an organic light-emitting layer located between the anode and the cathode.

Adjacent pixels may be partitioned by a pixel-defining layer (or bank). The pixel-defining layer may include, or define, openings allocated respectively corresponding to the pixels. An area corresponding to the opening may be defined as a light-emitting area, and other areas may be defined as a non-light-emitting area. To implement a high-resolution organic light-emitting display device, it may be suitable to minimize the non-light-emitting area.

### SUMMARY

Embodiments provide a display device with improved display quality.

Embodiments provide a method of manufacturing the display device.

A display device according to one or more embodiments includes a substrate including a main pixel area, and an auxiliary pixel area adjacent to the main pixel area, a main transistor above the substrate, and overlapping the main pixel area, an auxiliary transistor above the substrate, and overlapping the auxiliary pixel area, a lower electrode above the main transistor, connected to the main transistor, and overlapping the main pixel area, a pixel-defining layer above the substrate, covering a side portion of the lower electrode, overlapping the auxiliary pixel area, and defining a cutout portion, and an auxiliary lower electrode filling the cutout portion, connected to the auxiliary transistor, and having a same height as the cutout portion.

The auxiliary lower electrode may partially overlap the lower electrode.

The cutout portion may expose an upper surface of the auxiliary lower electrode.

The pixel-defining layer may include a first portion overlapping the cutout portion, and a second portion not overlapping the cutout portion.

An upper surface of the second portion of the pixel-defining layer, and an upper surface of the auxiliary lower electrode, may be at a same plane.

The main pixel area may include a first main pixel area, and a second main pixel area spaced from the first main pixel area with the auxiliary pixel area interposed therebetween.

The second main pixel area may be spaced from the first main pixel area in a first direction, wherein a width of the second portion of the pixel-defining layer adjacent to the first main pixel area in the first direction is substantially equal to a width of the second portion of the pixel-defining layer adjacent to the second main pixel area in the first direction.

The lower electrode and the auxiliary lower electrode may include a same material.

The main pixel area and the auxiliary pixel area may be repeatedly alternately arranged in a plan view.

Each of the lower electrode and the auxiliary lower electrode may be an anode electrode.

The display device may further include a light-emitting layer above the lower electrode, and covering the pixel-defining layer.

The light-emitting layer may cover an upper surface of the auxiliary lower electrode.

The light-emitting layer may not contact a side surface of the auxiliary lower electrode.

The display device may further include an upper electrode above the light-emitting layer.

A method of manufacturing a display device according to one or more embodiments includes forming a substrate including a main pixel area, and an auxiliary pixel area adjacent to the main pixel area, forming a main transistor overlapping the main pixel area above the substrate, forming an auxiliary transistor overlapping the auxiliary pixel area above the substrate, forming a lower electrode connected to the main transistor, and overlapping the main pixel area above the main transistor, forming a first preliminary pixel-defining layer above the lower electrode, forming an auxiliary lower electrode overlapping the auxiliary pixel area above the first preliminary pixel-defining layer, forming a second preliminary pixel-defining layer above the first preliminary pixel-defining layer and the auxiliary lower electrode, removing a portion of the second preliminary pixel-defining layer, and removing a portion of the first preliminary pixel-defining layer overlapping the main pixel area, and a portion of the second preliminary pixel-defining layer overlapping the main pixel area.

The removing the portion of the second preliminary pixel-defining layer may include removing the second preliminary pixel-defining layer up to an upper surface of the auxiliary lower electrode.

The auxiliary lower electrode may partially overlap the lower electrode.

The removing the first preliminary pixel-defining layer overlapping the main pixel area, and the second preliminary pixel-defining layer overlapping the main pixel area, may include forming a pixel-defining layer covering a side portion of the lower electrode, and including a first portion overlapping the auxiliary lower electrode and a second portion not overlapping the auxiliary lower electrode.

The method may further include forming a light-emitting layer above the lower electrode, covering the pixel-defining layer, covering an upper surface of the auxiliary lower electrode, and not contacting a side surface of the auxiliary lower electrode.

The method may further include forming an upper electrode on the light-emitting layer.

The display device according to one or more embodiments may include a substrate. The substrate may include a first main pixel area, a second main pixel area, and a first auxiliary pixel area located between the first main pixel area and the second main pixel area. The first pixel electrode may be located on the substrate. The first pixel electrode may overlap the first main pixel area. In addition, the second pixel electrode may be located on the substrate. The second pixel electrode may overlap the second main pixel area. In addition, the pixel-defining layer may be located on the substrate. The pixel-defining layer may overlap the first auxiliary pixel area. The pixel-defining layer may define a cutout portion. The auxiliary pixel electrode may fill the cutout portion.

The first pixel electrode may partially overlap the auxiliary pixel electrode. Accordingly, a distance between the first main pixel area and the first auxiliary pixel area may be reduced. In addition, the second pixel electrode may partially overlap the auxiliary pixel electrode. Accordingly, a distance between the second main pixel area and the first auxiliary pixel area may be reduced. Accordingly, resolution of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to one or more embodiments.

FIG. 2 is a cross-sectional view of the display device of FIG. 1 taken along the line I-I′ of FIG. 1.

FIG. 3 is a cross-sectional view illustrating an X-Y portion of the display device of FIG. 2.

FIG. 4 is a plan view illustrating the display device of FIG. 1.

FIGS. 5, 6, 7, 8, 9, 10, 11, and 12 are cross-sectional views illustrating a method of manufacturing the display device of FIG. 1.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

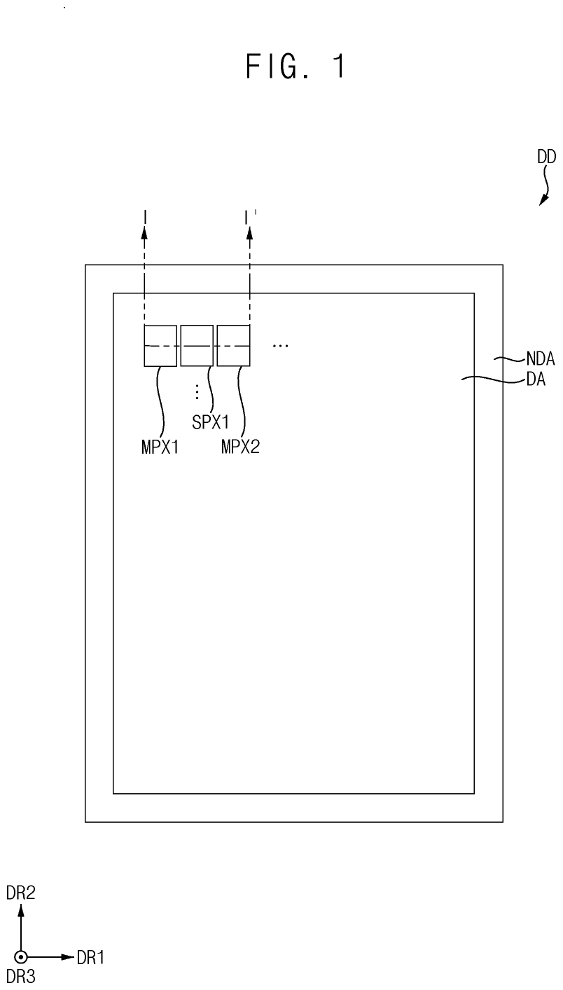

FIG. 1 is a plan view illustrating a display device according to one or more embodiments.

Referring to FIG. 1, a display device DD may include a display area DA and a non-display area NDA. The display area DA may be defined as an area that emits light. In addition, components that transmit signals to the display area DA may be located in the non-display area NDA.

A main pixel area may be located in the display area DA. For example, a first main pixel area MPX1 and a second main pixel area MPX2 may be located in the display area DA. In one or more embodiments, an auxiliary pixel area may be further located in the display area DA. The auxiliary pixel area may be adjacent to the main pixel area.

For example, a first auxiliary pixel area SPX1 may be located in the display area DA. The first auxiliary pixel area SPX1 may be adjacent to the first main pixel area MPX1 in a first direction DR1. In addition, the first auxiliary pixel area SPX1 may be adjacent to the second main pixel area MPX2 in a direction opposite to the first direction DR1. That is, the first auxiliary pixel area SPX1 may be located between the first main pixel area MPX1 and the second main pixel area MPX2.

The second main pixel area MPX2 may be spaced apart from the first main pixel area MPX1 in the first direction DR1. For example, the second main pixel area MPX2 may be spaced apart from the first main pixel area MPX1 with the first auxiliary pixel area SPX1 interposed therebetween.

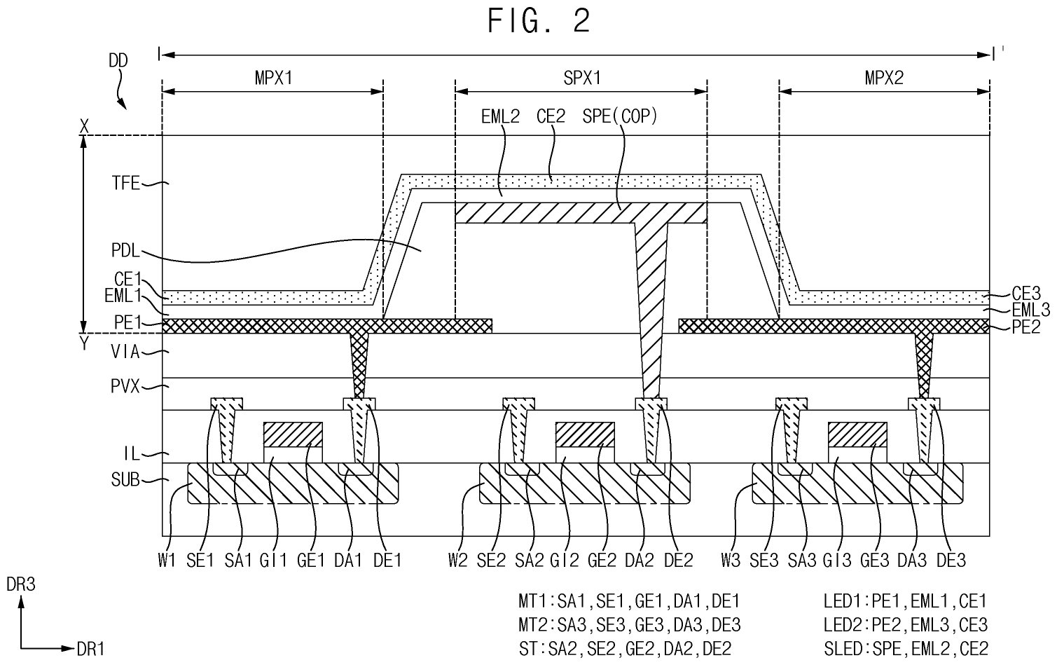

The first main pixel area MPX1 may be an area in which light is emitted from a first light-emitting element (e.g., a first light-emitting element LED1 of FIG. 2) to an outside of the display device DD.

In addition, the second main pixel area MPX2 may be an area in which light is emitted from a second light-emitting element (e.g., a second light-emitting element LED2 in FIG. 2) to the outside of the display device DD.

In addition, the first auxiliary pixel area SPX1 may be an area in which light is emitted from an auxiliary light-emitting element (e.g., an auxiliary light-emitting element SLED in FIG. 2) to the outside of the display device DD.

The non-display area NDA may be located around the display area DA. For example, the non-display area NDA may surround at least a portion of the display area DA (e.g., in plan view). A driver may be located in the non-display area NDA. The driver may provide a signal or a voltage to each of the main pixel area and the auxiliary pixel area. The driver may include a data driver, a gate driver, and the like. The non-display area NDA may not display an image.

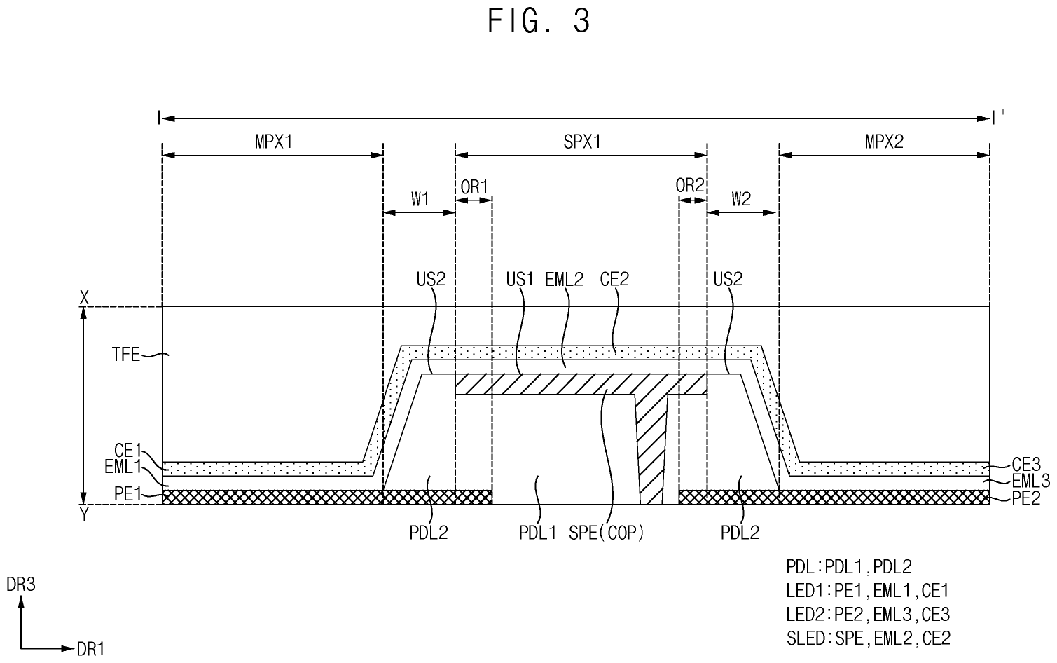

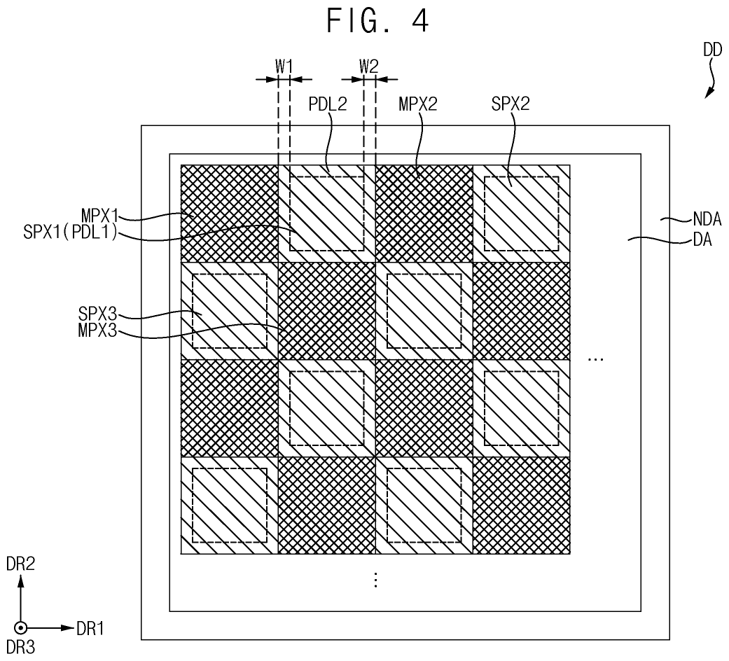

FIG. 2 is a cross-sectional view of the display device of FIG. 1 taken along the line I-I′ of FIG. 1. FIG. 3 is a cross-sectional view illustrating an X-Y portion of the display device of FIG. 2. FIG. 4 is a plan view illustrating the display device of FIG. 1.

Referring to FIG. 2, the display device DD may include a substrate SUB, an insulating layer IL, a passivation layer PVX, a via insulating layer VIA, a first gate-insulating layer GI1, a second gate-insulating layer GI2, a third gate-insulating layer GI3, a first main transistor MT1, a second main transistor MT2, an auxiliary transistor ST, a first pixel electrode PE1, a second pixel electrode PE2, an auxiliary pixel electrode SPE, a first light-emitting layer EML1, a second light-emitting layer EML2, a third light-emitting layer EML3, a first common electrode CE1, a second common electrode CE2, a third common electrode CE3, a pixel-defining layer PDL, and an encapsulating layer TFE.

The substrate SUB may be a silicon substrate. In detail, the substrate SUB may be a p-type silicon substrate or an n-type silicon substrate. In this case, p may mean a hole, and n may mean electron. The substrate SUB may include a first well area W1, a second well area W2, and a third well area W3.

The first well area W1 may overlap the first main pixel area MPX1. The first well area W1 may be a p-well or an n-well according to a type of the first main transistor MT1 and the type of the substrate SUB.

In addition, the second well area W2 may overlap the first auxiliary pixel area SPX1. The second well area W2 may be a p-well or an n-well according to a type of the auxiliary transistor ST and a type of the substrate SUB.

In addition, the third well area W3 may overlap the second main pixel area MPX2. The third well area W3 may be a p-well or an n-well according to a type of the second main transistor MT2 and a type of the substrate SUB.

The substrate SUB may include a first source area SA1 and a first drain area DA1. Each of the first source area SA1 and the first drain area DA1 may partially overlap the first main pixel area MPX1.

In one or more embodiments, the first source area SA1 and the first drain area DA1 may be an n-source area and an n-drain area, respectively. In one or more other embodiments, the first source area SA1 and the first drain area DA1 may be a p-source area and a p-drain area, respectively.

In addition, the substrate SUB may include a second source area SA2 and a second drain area DA2. Each of the second source area SA2 and the second drain area DA2 may partially overlap the first auxiliary pixel area SPX1.

In one or more embodiments, the second source area SA2 and the second drain area DA2 may be an n-source area and an n-drain area, respectively. In one or more other embodiments, the second source area SA2 and the second drain area DA2 may be a p-source area and a p-drain area, respectively.

In addition, the substrate SUB may include a third source area SA3 and a third drain area DA3. Each of the third source area SA3 and the third drain area DA3 may partially overlap the second main pixel area MPX2.

In one or more embodiments, the third source area SA3 and the third drain area DA3 may be an n-source area and an n-drain area, respectively. In one or more other embodiments, the third source area SA3 and the third drain area DA3 may be a p-source area and a p-drain area, respectively.

The first gate-insulating layer GI1, the second gate-insulating layer GI2, and the third gate-insulating layer GI3 may be located on the substrate SUB. The first gate-insulating layer GI1 may be located on the first well area W1. In addition, the second gate-insulating layer GI2 may be located on the second well area W2. In addition, the third gate-insulating layer GI3 may be located on the third well area W3.

Each of the first gate-insulating layer GI1, the second gate-insulating layer GI2, and the third gate-insulating layer GI3 may include silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The first gate electrode GE1 may be located on the first gate-insulating layer GI1. In addition, the second gate electrode GE2 may be located on the second gate-insulating layer GI2. In addition, the third gate electrode GE3 may be located on the third gate-insulating layer GI3. Each of the first gate electrode GE1, the second gate electrode GE2, and the third gate electrode GE3 may include a metal, an alloy metal nitride, a conductive metal oxide, a transparent conductive material, or the like.

Examples of the metal may include silver (“Ag”), molybdenum (“Mo”), aluminum (“AI”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other.

Examples of the conductive metal oxide may include Indium tin oxide, indium zinc oxide, or the like. In addition, examples of the metal nitride may include aluminum nitride (“AlNₓ”), tungsten nitride (“WNₓ”), chromium nitride (“CrNₓ”), or the like. These materials may be used alone or in combination with each other.

The insulating layer IL may be located on the substrate SUB. The insulating layer IL may sufficiently cover the first gate electrode GE1, the second gate electrode GE2, and the third gate electrode GE3.

For example, the insulating layer IL may include an inorganic material, such as silicon oxide, silicon nitride, silicon carbide, silicon oxynitride, silicon oxycarbide, or the like. These materials may be used alone or in combination with each other.

The first source electrode SE1 and the first drain electrode DE1 may be located on the insulating layer IL. The first source electrode SE1 may be connected to the first source area SA1 through a first contact hole penetrating the insulating layer IL. In addition, the first drain electrode DE1 may be connected to the first drain area DA1 through a second contact hole penetrating the insulating layer IL.

In addition, the second source electrode SE2 and the second drain electrode DE2 may be located on the insulating layer IL. The second source electrode SE2 may be connected to the second source area SA2 through a third contact hole penetrating the insulating layer IL. In addition, the second drain electrode DE2 may be connected to the second drain area DA2 through a fourth contact hole penetrating the insulating layer IL.

In addition, the third source electrode SE3 and the third drain electrode DE3 may be located on the insulating layer IL. The third source electrode SE3 may be connected to the third source area SA3 through a fifth contact hole penetrating the insulating layer IL. In addition, the third drain electrode DE3 may be connected to the third drain area DA3 through a sixth contact hole penetrating the insulating layer IL.

The first main transistor MT1 may include the first source area SA1, the first source electrode SE1, the first gate electrode GE1, the first drain area DA1, and the first drain electrode DE1.

In addition, the second main transistor MT2 may include the third source area SA3, the third source electrode SE3, the third gate electrode GE3, the third drain area DA3, and the third drain electrode DE3.

In addition, the auxiliary transistor ST may include the second source area SA2, the second source electrode SE2, the second gate electrode GE2, the second drain area DA2, and the second drain electrode DE2.

In one or more embodiments, each of the first main transistor MT1, the second main transistor MT2, and the auxiliary transistor ST may be a MOSFET. However, this disclosure is not limited thereto, and in one or more other embodiments, each of the first main transistor MT1, the second main transistor MT2, and the auxiliary transistor ST may be a TFT. In this case, the substrate SUB may be a glass substrate, a polyimide substrate, or the like.

The passivation layer PVX may be located on the insulating layer IL. The passivation layer PVX may sufficiently cover the first source electrode SE1, the second source electrode SE2, the third source electrode SE3, the first drain electrode DE1, the second drain electrode DE2, and the third drain electrode DE3.

The passivation layer PVX may include an inorganic insulating material. Examples of materials that can be used as the passivation layer PVX may include silicon oxide, silicon nitride, silicon oxynitride, or the like. These may be used alone or in combination with each other.

The via insulating layer VIA may be located on the passivation layer PVX. The via insulating layer VIA may include an organic material. For example, the via insulating layer VIA may include organic materials, such as phenolic resin, acrylic resin, polyimide resin, polyamide resin, siloxane resin, epoxy resin, or the like. These materials may be used alone or in combination with each other.

The first pixel electrode PE1 and the second pixel electrode PE2 may be located on the via insulating layer VIA.

The first pixel electrode PE1 may be connected to the first main transistor MT1. For example, the first pixel electrode PE1 may be connected to the first drain electrode DE1 through a seventh contact hole penetrating the via insulating layer VIA and the passivation layer PVX. The first pixel electrode PE1 may overlap the first main pixel area MPX1. In one or more embodiments, the first pixel electrode PE1 may partially overlap the first auxiliary pixel area SPX1.

The second pixel electrode PE2 may be connected to the second main transistor MT2. For example, the second pixel electrode PE2 may be connected to the third drain electrode DE3 through an eighth contact hole penetrating the via insulating layer VIA and the passivation layer PVX. The second pixel electrode PE2 may overlap the second main pixel area MPX2. In one or more embodiments, the second pixel electrode PE2 may partially overlap the first auxiliary pixel area SPX1.

Each of the first pixel electrode PE1 and the second pixel electrode PE2 may be referred to as a lower electrode. In addition, each of the first pixel electrode PE1 and the second pixel electrode PE2 may be an anode electrode.

The pixel-defining layer PDL may be located on the first pixel electrode PE1, the second pixel electrode PE2, and the via insulating layer VIA. The pixel-defining layer PDL may overlap the first auxiliary pixel area SPX1. In addition, the pixel-defining layer PDL may cover a side portion of the first pixel electrode PE1. In addition, the pixel-defining layer PDL may cover a side portion of the second pixel electrode PE2.

The pixel-defining layer PDL may define a cutout portion COP. The cutout portion COP may be a portion obtained by removing at least a portion of the pixel-defining layer PDL from an upper surface of the pixel-defining layer PDL. The cutout portion COP may overlap the first auxiliary pixel area SPX1.

In one or more embodiments, the pixel-defining layer PDL may include an organic material. In one or more embodiments, the pixel-defining layer PDL may include an organic material, such as an epoxy resin, a siloxane resin, or the like. These materials may be used alone or in combination with each other. In one or more other embodiments, the pixel-defining layer PDL may further include a light-blocking material containing a black pigment, a black dye, and the like.

The pixel-defining layer PDL may include an organic material. For example, the pixel-defining layer PDL may include a photoresist, a polyacrylic resin, a polyimide resin, a polyamide resin, a siloxane resin, an acrylic resin, an epoxy resin, or the like. These materials may be used alone or in combination with each other. In one or more other embodiments, the pixel-defining layer PDL may include an inorganic material.

The auxiliary pixel electrode SPE may fill the cutout portion COP. That is, the auxiliary pixel electrode SPE may overlap the first auxiliary pixel area SPX1. An upper surface of the auxiliary pixel electrode SPE may be exposed through the cutout portion COP. The auxiliary pixel electrode SPE may be connected to the auxiliary transistor ST. For example, the auxiliary pixel electrode SPE may be connected to the second drain electrode DE2 through a ninth contact hole penetrating the pixel-defining layer PDL, the via insulating layer VIA, and the passivation layer PVX.

In one or more embodiments, the first pixel electrode PE1, the second pixel electrode PE2, and the auxiliary pixel electrode SPE may include the same material. In one or more other embodiments, the first pixel electrode PE1, the second pixel electrode PE2, and the auxiliary pixel electrode SPE may include different materials. In addition, the auxiliary pixel electrode SPE may be referred to as an auxiliary lower electrode. In addition, the auxiliary pixel electrode SPE may be an anode electrode.

The first light-emitting layer EML1 may be located on the first pixel electrode PE1. The first light-emitting layer EML1 may overlap the first main pixel area MPX1. A hole provided by the first pixel electrode PE1 and an electron provided by the first common electrode CE1 may be combined in the first light-emitting layer EML1 to form a first exciton. Light may be emitted from the first light-emitting layer EML1 as the first exciton changes from an excited state to a ground state.

In addition, the second light-emitting layer EML2 may be located on the pixel-defining layer PDL. The second light-emitting layer EML2 may overlap the first auxiliary pixel area SPX1. The second light-emitting layer EML2 may cover an upper surface of the auxiliary pixel electrode SPE. A hole provided by the auxiliary pixel electrode SPE and an electron provided by the second common electrode CE2 may be combined in the second light-emitting layer EML2 to form a second exciton. Light may be emitted from the second light-emitting layer EML2 as the second exciton changes from an excited state to a ground state.

In addition, the third light-emitting layer EML3 may be located on the second pixel electrode PE2. The third light-emitting layer EML3 may overlap the second main pixel area MPX2. A hole provided by the second pixel electrode PE2 and an electron provided by the third common electrode CE3 may be combined in the third light-emitting layer EML3 to form a third exciton. Light may be emitted from the third light-emitting layer EML3 as the third exciton changes from an excited state to a ground state.

In one or more embodiments, the first light-emitting layer EML1 and the second light-emitting layer EML2 may be connected to each other. In addition, the second light-emitting layer EML2 and the third light-emitting layer EML3 may be connected to each other. That is, the first light-emitting layer EML1, the second light-emitting layer EML2, and the third light-emitting layer EML3 may be integrally formed to form a single light-emitting layer. In this case, the light-emitting layer may entirely cover the pixel-defining layer PDL.

In one or more other embodiments, the first light-emitting layer EML1 and the second light-emitting layer EML2 may be separated from each other. In addition, the second light-emitting layer EML2 and the third light-emitting layer EML3 may be separated from each other.

The first common electrode CE1 may be located on the first light-emitting layer EML1. In addition, the second common electrode CE2 may be located on the second light-emitting layer EML2. In addition, the third common electrode CE3 may be located on the third light-emitting layer EML3.

In one or more embodiments, the first common electrode CE1 and the second common electrode CE2 may be connected to each other. In addition, the second common electrode CE2 and the third common electrode CE3 may be connected to each other. That is, the first common electrode CE1, the second common electrode CE2, and the third common electrode CE3 may be integrally formed to form a single common electrode.

In one or more other embodiments, the first common electrode CE1 and the second common electrode CE2 may be separated from each other. In addition, the second common electrode CE2 and the third common electrode CE3 may be separated from each other.

Each of the first common electrode CE1, the second common electrode CE2, and the third common electrode CE3 may include an alloy, a metal nitride, a conductive metal oxide, a transparent conductive material, or the like. These materials may be used alone or in combination with each other. For example, each of the first common electrode CE1, the second common electrode CE2, and the third common electrode CE3 may be a cathode electrode.

A first light-emitting element LED1 may include the first pixel electrode PE1, the first light-emitting layer EML1, and the first common electrode CE1. A second light-emitting element LED2 may include the second pixel electrode PE2, the third light-emitting layer EML3, and the third common electrode CE3. An auxiliary light-emitting element SLED may include the auxiliary pixel electrode SPE, the second light-emitting layer EML2, and the second common electrode CE2.

The encapsulation layer TFE may be located on the first common electrode CE1, the second common electrode CE2, and the third common electrode CE3. The encapsulation layer TFE may reduce or prevent the likelihood of an impurity, moisture, and the like penetrating into the first light-emitting element LED1, the second light-emitting element LED2, or the auxiliary light-emitting element SLED.

The encapsulation layer TFE may include at least one inorganic layer and at least one organic layer. For example, the inorganic layer may include silicon oxide, silicon nitride, silicon oxynitride, and the like. These materials may be used alone or in combination with each other. The organic layer may include a polymer cured product, such as polyacrylate.

Referring to FIGS. 3 and 4, the pixel-defining layer PDL may include a first portion PDL1 and a second portion PDL2. The first portion PDL1 may overlap the cutout portion COP. That is, the first portion PDL1 may overlap the auxiliary pixel electrode SPE.

The second portion PDL2 may not overlap (e.g., might not entirely overlap) the cutout portion COP. That is, the second portion PDL2 may not overlap (e.g., might not entirely overlap) the auxiliary pixel electrode SPE. The second portion PDL2 may surround the first portion PDL1.

The auxiliary pixel electrode SPE may have a first upper surface US1. The first upper surface US1 may be a surface that is in contact with the second light-emitting layer EML2. In addition, the second portion PDL2 may have a second upper surface US2. The second upper surface US2 may be a surface that is in contact with the second light-emitting layer EML2.

In one or more embodiments, the first upper surface US1 and the second upper surface US2 may be located on the same plane. That is, a width of the cutout portion COP in the third direction DR3 and a width of the auxiliary pixel electrode SPE in the third direction DR3 may be the same.

In one or more embodiments, the second light-emitting layer EML2 may be in contact with the first upper surface US1. In addition, the second light-emitting layer EML2 may not be in contact with a side surface of the auxiliary pixel electrode SPE.

As the second light-emitting layer EML2 does not contact the side surface of the auxiliary pixel electrode SPE, and as the first upper surface US1 and the second upper surface US2 are located on the same plane, a step may not occur in a portion of the second light-emitting layer EML2 overlapping the side surface of the auxiliary pixel electrode SPE. That is, a thickness of the portion of the second emission layer EML2 overlapping the side surface of the auxiliary pixel electrode SPE in the third direction DR3 may not be reduced (e.g., may not change). Therefore, it is possible to reduce or prevent the likelihood of a discharge phenomenon occurring due to excessive collection of charges in a portion of the second light-emitting layer EML2 and the second common electrode CE2 overlapping the side surface of the auxiliary electrode SPE.

In one or more embodiments, the first pixel electrode PE1 and the auxiliary pixel electrode SPE may partially overlap. That is, a first overlapping area OR1 in which the first pixel electrode PE1 and the auxiliary pixel electrode SPE overlap may be defined. Accordingly, a distance between the first main pixel area MPX1 and the first auxiliary pixel area SPX1 may be reduced. Accordingly, resolution of the display device DD may be improved.

In one or more embodiments, the second pixel electrode PE2 and the auxiliary pixel electrode SPE may partially overlap. That is, a second overlapping area OR2 in which the second pixel electrode PE2 and the auxiliary pixel electrode SPE overlap may be defined. Accordingly, a distance between the first auxiliary pixel area SPX1 and the second main pixel area MPX2 may be reduced. Accordingly, the resolution of the display device DD may be improved.

In one or more embodiments, a width W1 of the second portion PDL2 adjacent to the first main pixel area MPX1 in the first direction DR1, and a width W2 of the second portion PDL2 adjacent to the second main pixel area MPX2 in the first direction DR1. may be substantially the same. That is, a distance W1 between the first main pixel area MPX1 and the first auxiliary pixel area SPX1, and a distance W2 between the second main pixel area MPX2 and the first auxiliary pixel area SPX1, may be substantially the same as each other.

In one or more other embodiments, a width W1 of the second portion PDL2 adjacent to the first main pixel area MPX1 in the first direction DR1, and a width W2 of the second portion PDL2 adjacent to the second main pixel area MPX2 in the first direction DR1. may be different.

In one or more embodiments, the main pixel area and the auxiliary pixel area may be repeatedly located alternately in a plan view.

For example, the first auxiliary pixel area SPX1 may be located adjacent to the first main pixel area MPX1 in the first direction DR1. In addition, the second main pixel area MPX2 may be located adjacent to the first auxiliary pixel area SPX1 in the first direction DR1. In addition, as shown in FIG. 4, the second auxiliary pixel area SPX2 may be located adjacent to the second main pixel area MPX2 in the first direction DR1.

In addition, the third auxiliary pixel area SPX3 may be located adjacent to the first main pixel area MPX1 in a direction opposite to the second direction DR2. In addition, the third main pixel area MPX3 may be located adjacent to the third auxiliary pixel area SPX3 in the first direction DR1. That is, the third main pixel area MPX3 may be located adjacent to the first auxiliary pixel area SPX1 in the direction opposite to the second direction DR2.

A pixel electrode including the same material as the first pixel electrode PE1 and the second pixel electrode PE2, and located on the same layer as the first pixel electrode PE1 and the second pixel electrode PE2, may be located in each of the main pixel areas. In addition, an auxiliary pixel electrode including the same material as the auxiliary pixel electrode SPE, and located on the same layer as the auxiliary pixel electrode SPE, may be located in each of the auxiliary pixel areas.

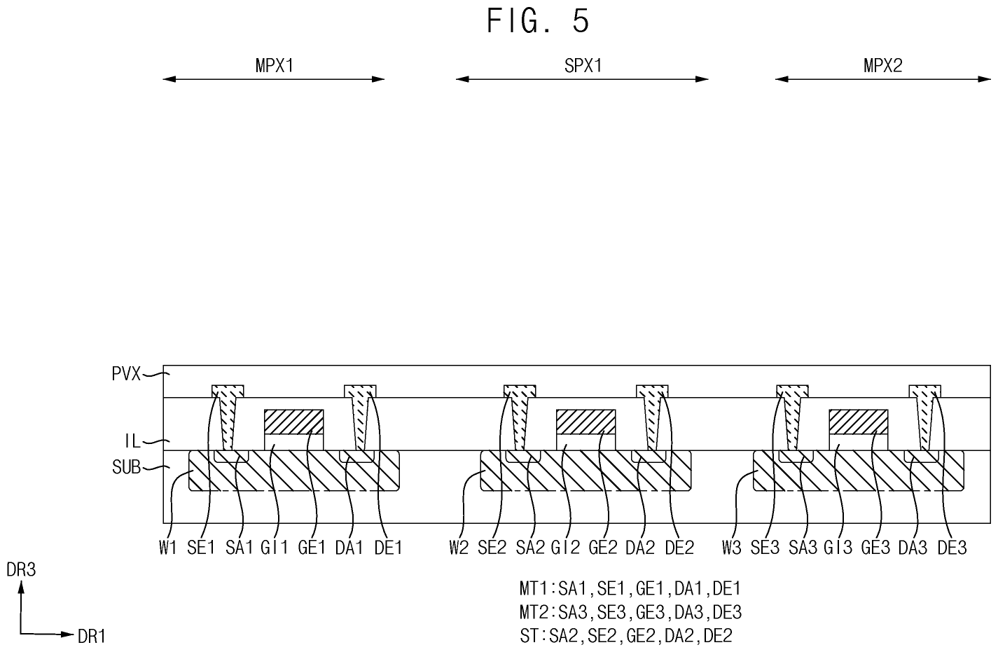

FIGS. 5, 6, 7, 8, 9, 10, 11, and 12 are cross-sectional views illustrating a method of manufacturing the display device of FIG. 1.

Referring to FIG. 5, the first well area W1 may be formed in the substrate SUB. The first well area W1 may overlap the first main pixel area MPX1. In addition, the second well area W2 may be formed in the substrate SUB. The second well area W2 may overlap the first auxiliary pixel area SPX1. In addition, the third well area W3 may be formed in the substrate SUB. The third well area W3 may overlap the second main pixel area MPX2.

The first source area SA1 and the first drain area DA1 may be formed on the substrate SUB. Each of the first source area SA1 and the first drain area DA1 may partially overlap the first main pixel area MPX1.

In addition, the second source area SA2 and the second drain area DA2 may be formed on the substrate SUB. Each of the second source area SA2 and the second drain area DA2 may partially overlap the first auxiliary pixel area SPX1.

In addition, the third source area SA3 and the third drain area DA3 may be formed on the substrate SUB. Each of the third source area SA3 and the third drain area DA3 may partially overlap the second main pixel area MPX2.

The first gate-insulating layer GI1, the second gate-insulating layer GI2, and the third gate-insulating layer GI3 may be formed on the substrate SUB. The first gate-insulating layer GI1 may be formed on the first well area W1. In addition, the second gate-insulating layer GI2 may be formed on the second well area W2. In addition, the third gate-insulating layer GI3 may be formed on the third well area W3.

The first gate electrode GE1 may be formed on the first gate-insulating layer GI1. In addition, the second gate electrode GE2 may be formed on the second gate-insulating layer GI2. In addition, the third gate electrode GE3 may be formed on the third gate-insulating layer GI3.

The insulating layer IL may be formed on the substrate SUB. The insulating layer IL may sufficiently cover the first gate electrode GE1, the second gate electrode GE2, and the third gate electrode GE3.

The first source electrode SE1 and the first drain electrode DE1 may be formed on the insulating layer IL. The first source electrode SE1 may be connected to the first source area SA1 through the first contact hole penetrating the insulating layer IL. In addition, the first drain electrode DE1 may be connected to the first drain area DA1 through the second contact hole penetrating the insulating layer IL.

In addition, the second source electrode SE2 and the second drain electrode DE2 may be formed on the insulating layer IL. The second source electrode SE2 may be connected to the second source area SA2 through the third contact hole penetrating the insulating layer IL. In addition, the second drain electrode DE2 may be connected to the second drain area DA2 through the fourth contact hole penetrating the insulating layer IL.

In addition, the third source electrode SE3 and the third drain electrode DE3 may be formed on the insulating layer IL. The third source electrode SE3 may be connected to the third source area SA3 through the fifth contact hole penetrating the insulating layer IL. In addition, the third drain electrode DE3 may be connected to the third drain area DA3 through the sixth contact hole penetrating the insulating layer IL.

The first main transistor MT1 may include the first source area SA1, the first source electrode SE1, the first gate electrode GE1, the first drain area DA1, and the first drain electrode DE1.

In addition, the second main transistor MT2 may include the third source area SA3, the third source electrode SE3, the third gate electrode GE3, the third drain area DA3, and the third drain electrode DE3.

In addition, the auxiliary transistor ST may include the second source area SA2, the second source electrode SE2, the second gate electrode GE2, the second drain area DA2, and the second drain electrode DE2.

The passivation layer PVX may be formed on the insulating layer IL. The passivation layer PVX may sufficiently cover the first source electrode SE1, the second source electrode SE2, the third source electrode SE3, the first drain electrode DE1, the second drain electrode DE2, and the third drain electrode DE3.

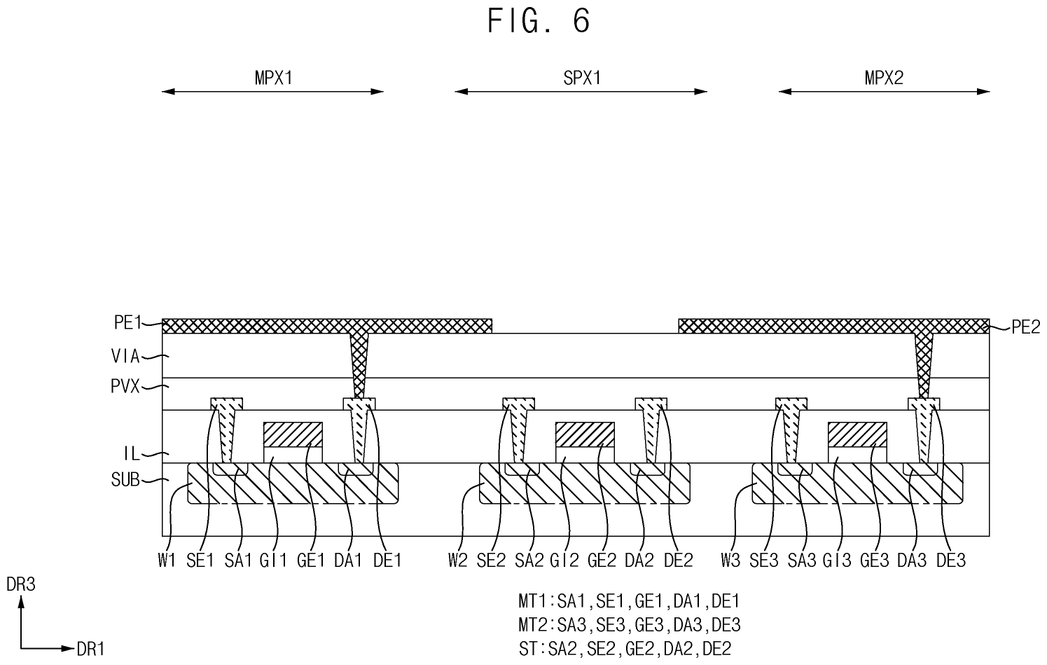

Referring to FIG. 6, the via insulating layer VIA may be formed on the passivation layer PVX. In addition, the first pixel electrode PE1 and the second pixel electrode PE2 may be formed on the via insulating layer VIA.

The first pixel electrode PE1 may be connected to the first main transistor MT1. For example, the first pixel electrode PE1 may be connected to the first drain electrode DE1 through the seventh contact hole penetrating the via insulating layer VIA and the passivation layer PVX. The first pixel electrode PE1 may overlap the first main pixel area MPX1. In one or more embodiments, the first pixel electrode PE1 may partially overlap the first auxiliary pixel electrode SPX1.

The second pixel electrode PE2 may be connected to the second main transistor MT2. For example, the second pixel electrode PE2 may be connected to the third drain electrode DE3 through the eighth contact hole penetrating the via insulating layer VIA and the passivation layer PVX. The second pixel electrode PE2 may overlap the second main pixel area MPX2. In one or more embodiments, the second pixel electrode PE2 may partially overlap the first auxiliary pixel area SPX1.

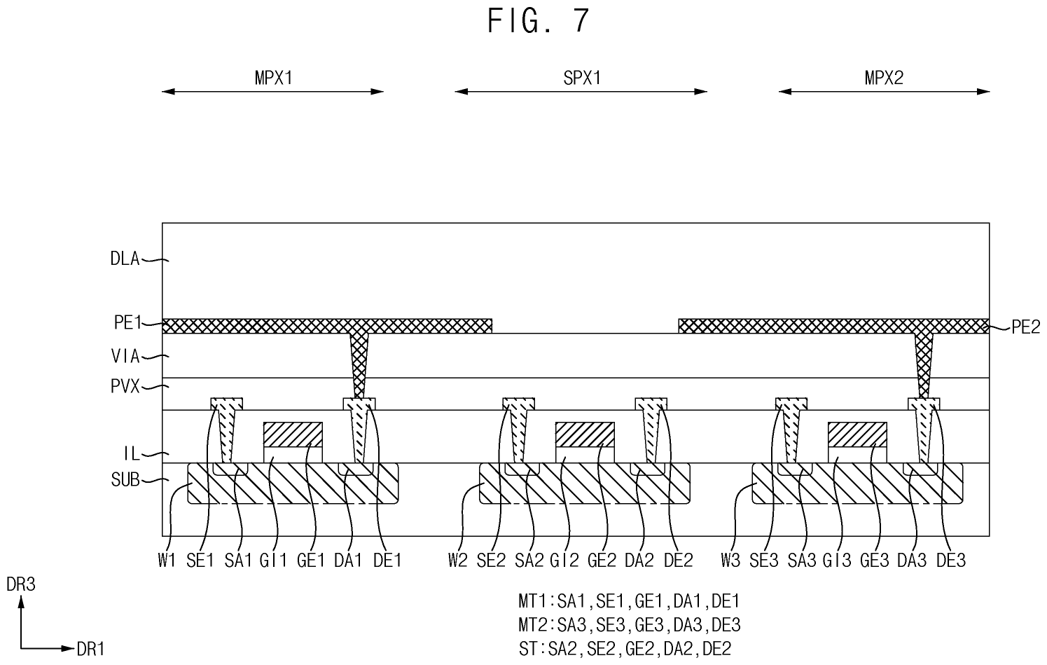

Referring to FIG. 7, a first preliminary pixel-defining layer DLA may be formed on the first pixel electrode PE1, the via insulating layer VIA, and the second pixel electrode PE2.

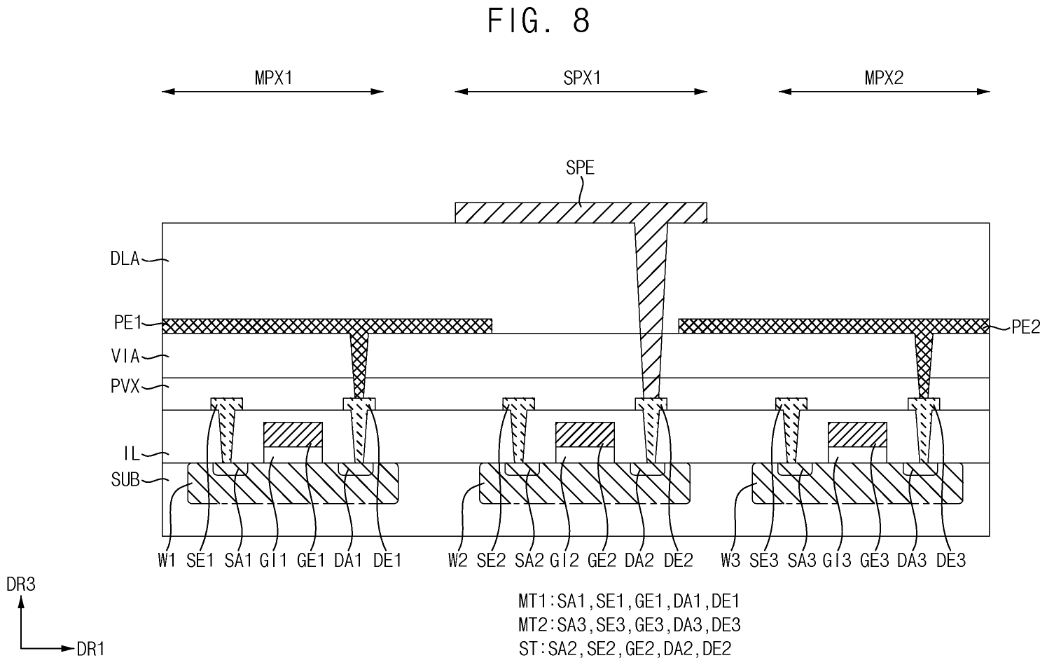

Referring to FIG. 8, The auxiliary pixel electrode SPE may be formed on the first preliminary pixel-defining layer DLA. The auxiliary pixel electrode SPE may overlap the first auxiliary pixel area SPX1.

The auxiliary pixel electrode SPE may be connected to the auxiliary transistor ST. For example, the auxiliary pixel electrode SPE may be connected to the second drain electrode DE2 through the ninth contact hole penetrating the first preliminary pixel-defining layer DLA, the via insulating layer VIA, and the passivation layer PVX.

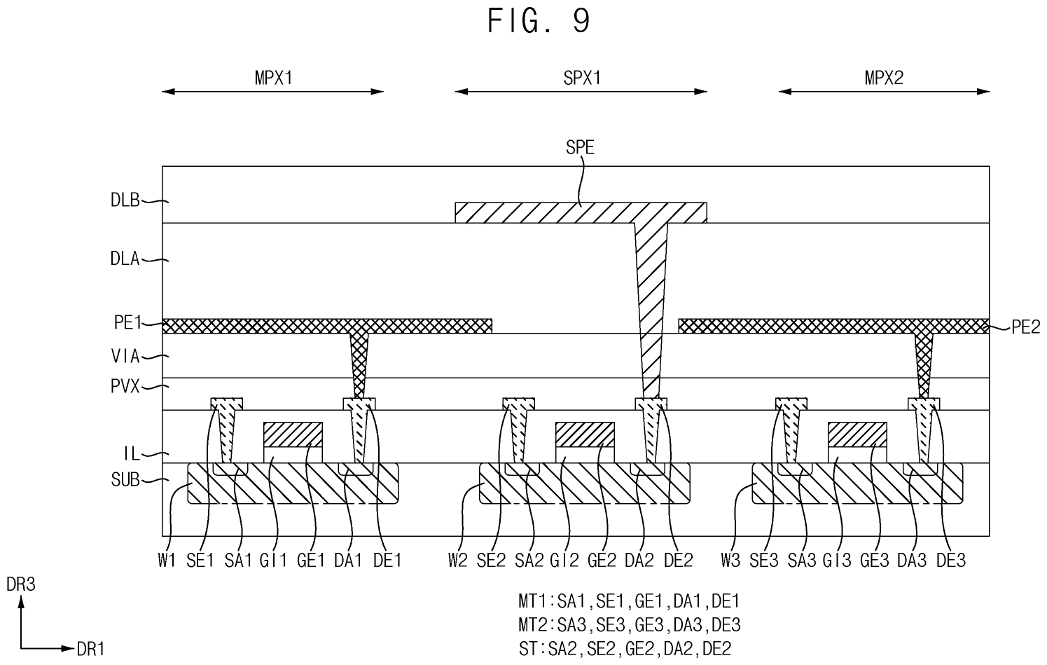

Referring to FIG. 9, a second preliminary pixel-defining layer DLB may be formed on the first preliminary pixel-defining layer DLA and the auxiliary pixel electrode SPE.

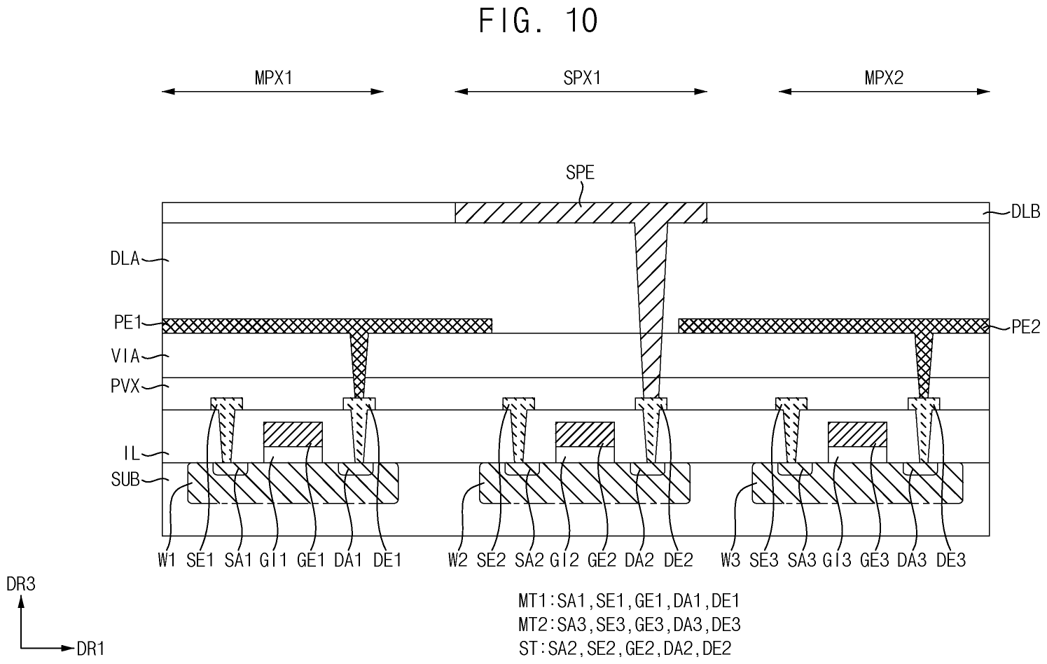

Referring to FIG. 10, a portion of the second preliminary pixel-defining layer DLB may be removed. In one or more embodiments, the second preliminary pixel-defining layer DLB may be removed up to a top surface of the auxiliary pixel electrode SPE. For example, the portion of the second preliminary pixel-defining layer DLB may be removed through a chemical mechanical polishing process.

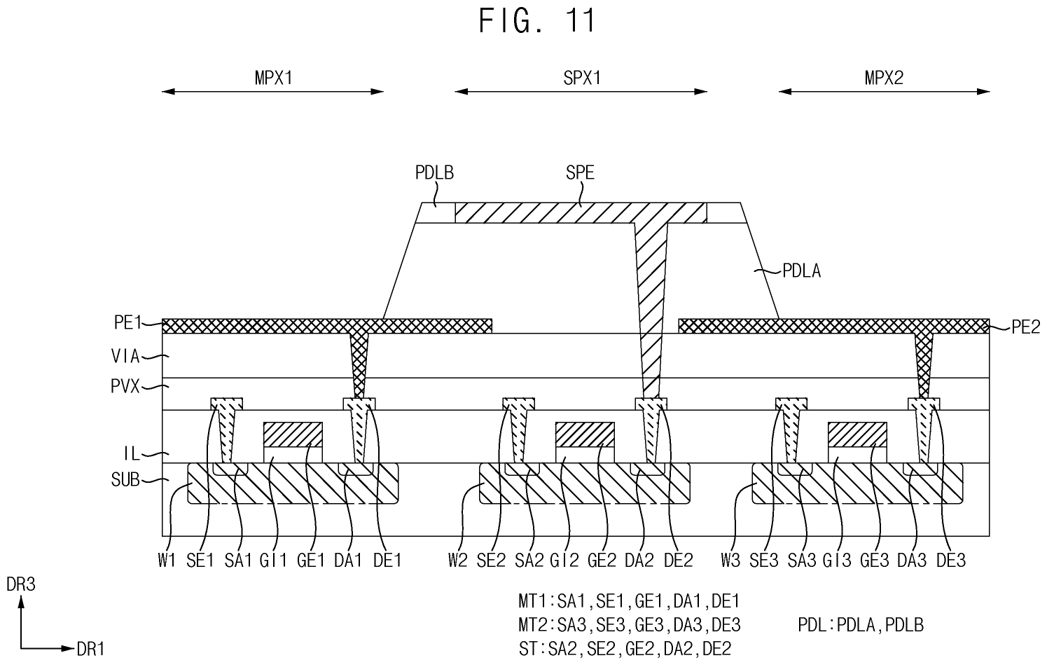

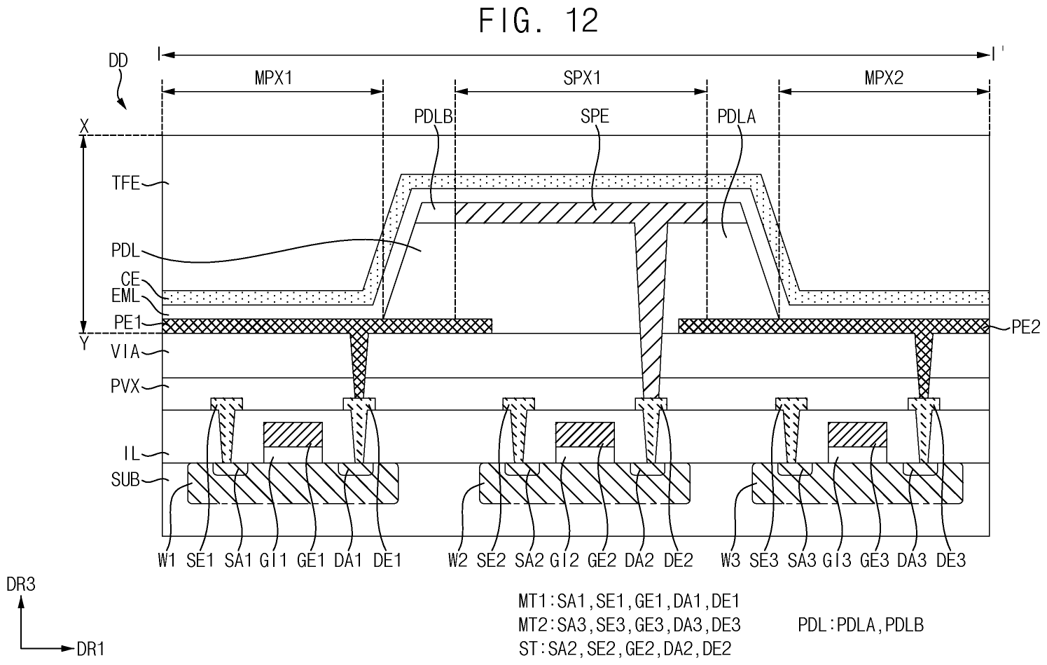

Referring to FIGS. 11 and 12, a first portion of the first preliminary pixel-defining layer DLA, and a first portion of the second preliminary pixel-defining layer DLB, may be removed. Each of the first portion of the first preliminary pixel-defining layer DLA, and the first portion of the second preliminary pixel-defining layer DLB, may overlap the first main pixel area MPX1

In addition, a second portion of the first preliminary pixel-defining layer DLA, and a second portion of the second preliminary pixel-defining layer DLB, may be removed. Each of the second portion of the first preliminary pixel-defining layer DLA, and the second portion of the second preliminary pixel-defining layer DLB, may overlap the second main pixel area MPX2.

Accordingly, a first pixel-defining layer PDLA may be formed. In addition, a second pixel-defining layer PDLB located on the first pixel-defining layer PDLA may be formed. That is, the pixel-defining layer PDL including the first pixel-defining layer PDLA and the second pixel-defining layer PDLB may be formed. The pixel-defining layer PDL may cover a side portion of the first pixel electrode PE1. In addition, the pixel-defining layer PDL may cover a side portion of the second pixel electrode PE2.

The pixel-defining layer PDL may include a first portion (e.g., the first portion PDL1 of FIG. 3) and a second portion (e.g., the second portion PDL2 of FIG. 3). The first portion of the pixel-defining layer PDL may overlap the auxiliary pixel electrode SPE. In addition, the second portion of the pixel-defining layer PDL may not overlap the auxiliary pixel electrode SPE.

Referring to FIG. 12, a light-emitting layer EML may be formed. In detail, the light-emitting layer EML may be formed on the first pixel electrode PE1. In addition, the light-emitting layer EML may be formed on the second pixel electrode PE2. In addition, the light-emitting layer EML may cover the pixel-defining layer PDL. In addition, the light-emitting layer EML may cover an upper surface of the auxiliary pixel electrode SPE. In addition, the light-emitting layer EML may be formed not to be in contact with a side surface of the auxiliary pixel electrode SPE.

The common electrode CE may be formed on the light-emitting layer EML.

The present disclosure can be applied to various display devices. For example, the present disclosure is applicable to various display devices, such as display devices for vehicles, ships, and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and aspects of the present disclosure. Accordingly, all such modifications are intended to be included within the scope of the present disclosure as defined in the claims. Therefore, it is to be understood that the foregoing is illustrative of various embodiments and is not to be construed as limited to the embodiments disclosed, and that modifications to the disclosed embodiments, as well as other embodiments, are intended to be included within the scope of the appended claims, with functional equivalents thereof to be included therein.

What is claimed is:

1. A display device comprising:
a substrate comprising a main pixel area, and an auxiliary pixel area adjacent to the main pixel area;
a main transistor above the substrate, and overlapping the main pixel area;
an auxiliary transistor above the substrate, and overlapping the auxiliary pixel area;
a lower electrode above the main transistor, connected to the main transistor, and overlapping the main pixel area;
a pixel-defining layer above the substrate, covering a side portion of the lower electrode, overlapping the auxiliary pixel area, and defining a cutout portion; and
an auxiliary lower electrode filling the cutout portion, connected to the auxiliary transistor, and having a same height as the cutout portion.

2. The display device of claim 1, wherein the auxiliary lower electrode partially overlaps the lower electrode.

3. The display device of claim 1, wherein the cutout portion exposes an upper surface of the auxiliary lower electrode.

4. The display device of claim 1, wherein the pixel-defining layer comprises a first portion overlapping the cutout portion, and a second portion not overlapping the cutout portion.

5. The display device of claim 4, wherein an upper surface of the second portion of the pixel-defining layer, and an upper surface of the auxiliary lower electrode, are at a same plane.

6. The display device of claim 5, wherein the main pixel area comprises:
a first main pixel area; and
a second main pixel area spaced from the first main pixel area with the auxiliary pixel area interposed therebetween.

7. The display device of claim 6, wherein the second main pixel area is spaced from the first main pixel area in a first direction, and
wherein a width of the second portion of the pixel-defining layer adjacent to the first main pixel area in the first direction is substantially equal to a width of the second portion of the pixel-defining layer adjacent to the second main pixel area in the first direction.

8. The display device of claim 1, wherein the lower electrode and the auxiliary lower electrode comprise a same material.

9. The display device of claim 1, wherein the main pixel area and the auxiliary pixel area are repeatedly alternately arranged in a plan view.

10. The display device of claim 1, wherein each of the lower electrode and the auxiliary lower electrode is an anode electrode.

11. The display device of claim 1, further comprising a light-emitting layer above the lower electrode, and covering the pixel-defining layer.

12. The display device of claim 11, wherein the light-emitting layer covers an upper surface of the auxiliary lower electrode.

13. The display device of claim 12, wherein the light-emitting layer does not contact a side surface of the auxiliary lower electrode.

14. The display device of claim 13, further comprising an upper electrode above the light-emitting layer.

15. A method of manufacturing a display device comprising:
forming a substrate comprising a main pixel area, and an auxiliary pixel area adjacent to the main pixel area;
forming a main transistor overlapping the main pixel area above the substrate;
forming an auxiliary transistor overlapping the auxiliary pixel area above the substrate;
forming a lower electrode connected to the main transistor, and overlapping the main pixel area above the main transistor;
forming a first preliminary pixel-defining layer above the lower electrode;
forming an auxiliary lower electrode overlapping the auxiliary pixel area above the first preliminary pixel-defining layer;
forming a second preliminary pixel-defining layer above the first preliminary pixel-defining layer and the auxiliary lower electrode;
removing a portion of the second preliminary pixel-defining layer; and
removing a portion of the first preliminary pixel-defining layer overlapping the main pixel area, and a portion of the second preliminary pixel-defining layer overlapping the main pixel area.

16. The method of claim 15, wherein the removing the portion of the second preliminary pixel-defining layer comprises removing the second preliminary pixel-defining layer up to an upper surface of the auxiliary lower electrode.

17. The method of claim 15, wherein the auxiliary lower electrode partially overlaps the lower electrode.

18. The method of claim 15, wherein the removing the first preliminary pixel-defining layer overlapping the main pixel area, and the second preliminary pixel-defining layer overlapping the main pixel area, comprises forming a pixel-defining layer covering a side portion of the lower electrode, and comprising a first portion overlapping the auxiliary lower electrode and a second portion not overlapping the auxiliary lower electrode.

19. The method of claim 18, further comprising forming a light-emitting layer above the lower electrode, covering the pixel-defining layer, covering an upper surface of the auxiliary lower electrode, and not contacting a side surface of the auxiliary lower electrode.

20. The method of claim 19, further comprising forming an upper electrode on the light-emitting layer.
